(19) United States
(12) Patent Application Publication
(10) Pub. No.: US 2021/0035812 A1
(43) Pub. Date: Feb. 4, 2021

(54) CHEMICAL MECHANICAL POLISHING METHOD AND CHEMICAL MECHANICAL POLISHING DEVICE AND METHOD OF MANUFACTURING SEMICONDUCTOR DEVICE

(71) Applicant: SAMSUNG ELECTRONICS CO., LTD., Suwon-si (KR)

(72) Inventors: Do Yoon KIM, Hwaseong-si (KR); Kenji TAKAI, Hwaseong-si (KR)

(21) Appl. No.: 16/742,941

(22) Filed: Jan. 15, 2020

(30) Foreign Application Priority Data
Aug. 2, 2019 (KR) 10-2019-0094515

(51) Int. Cl. H01L 21/306; B24B 37/20; H01L 21/67; C09G 1/02; B24B 37/015

(52) U.S. Cl. CPC H01L 21/30625; B24B 37/20; B24B 37/015; C09G 1/02; H01L 21/67248

(57) ABSTRACT

A chemical mechanical polishing method that includes preparing a chemical mechanical polishing device including a platen, a polishing pad, and a polishing slurry supplier, supplying a hot liquid to an inside of the platen to adjust a surface temperature of the platen, disposing the semiconductor substrate and the polishing pad to face each other, supplying polishing slurry including carbon abrasives having an average particle diameter of less than about 10 nm between the semiconductor substrate and the polishing pad, and contacting the surface of the semiconductor substrate with the polishing pad to polish the semiconductor substrate., a method of manufacturing a semiconductor device using the chemical polishing method, and a chemical mechanical polishing device.

### CROSS-REFERENCE TO RELATED APPLICATION

This application claims priority to Korean Patent Application No. 10-2019-0094515, filed on Aug. 2, 2019, and all the benefits accruing therefrom under 35 U.S.C. § 119, the content of which in its entirety is herein incorporated by reference.

### BACKGROUND

### 1. Field

A chemical mechanical polishing method, a chemical mechanical polishing device, and a method of manufacturing a semiconductor device.

### 2. Description of the Related Art

A semiconductor device includes a structure having a planar surface, and the structure may be obtained by a polishing process. One example of the polishing process may be a chemical mechanical polishing (CMP). Chemical mechanical polishing is a process including providing a polishing slurry between a semiconductor substrate to be polished and a polishing pad and contacting the surface of the semiconductor substrate to the polishing pad to planarize a surface of the semiconductor substrate.

### SUMMARY

High performance or highly integrated semiconductor devices require a fine pitch structure of less than about 10 (nanometers) nm. A polishing slurry including abrasives having a particle diameter of several tens of nanometers like conventional silica may cause damage or shape deformations of the requisite fine pitch structure of a semiconductor device.

An embodiment provides a chemical mechanical polishing method that may improve polishing rate (e.g., a material removal rate) while reducing damage or shape deformation of the fine pitch structure of a semiconductor device.

Another embodiment provides a chemical mechanical polishing device capable of improving a polishing rate while reducing damage and shape deformation of the fine pitch structure of a semiconductor device.

Another embodiment provides a method of manufacturing a semiconductor device using the chemical mechanical polishing method.

According to an embodiment, a chemical mechanical polishing method includes preparing a chemical mechanical polishing device including a platen, a polishing pad, and a polishing slurry supplier, supplying a hot liquid to an inside of the platen to adjust, for example to raise a surface temperature of the platen, disposing the semiconductor substrate and the polishing pad to face each other, supplying a polishing slurry including carbon abrasives having an average particle diameter of less than about 10 nm between the semiconductor substrate and the polishing pad, and contacting the surface of the semiconductor substrate with the polishing pad to polish the semiconductor substrate.

The temperature of the hot liquid may be about 35° C. to about 90° C.

The surface temperature of the platen may be about 30° C. to about 80° C.

The surface temperature of the platen may be about 35° C. to 45° C.

The chemical mechanical polishing device may further include a hot liquid supply line connected to the platen, and the hot liquid may be supplied to the inside of the platen through the hot liquid supply line.

The adjusting or raising of the surface temperature of the platen may be performed before the supplying of the polishing slurry.

After the adjusting or raising of the surface temperature of the platen, a deviation of the surface temperature according to a position of the platen may be less than or equal to about 5%.

The chemical mechanical polishing method may further include heating the polishing slurry before the supplying of the polishing slurry.

The heating of the polishing slurry may include heating the polishing slurry to about 27° C. to about 90° C.

The hot liquid may be hot water.

The carbon abrasives may include fullerene or a fullerene derivative.

The carbon abrasives may include a hydrophilic fullerene having at least one hydrophilic functional group and the hydrophilic functional group may include at least one of a hydroxyl group, an amino group, a carbonyl group, a carboxylic group, a sulfhydryl group, or a phosphate group.

The carbon abrasives may include hydroxyl fullerene represented by Cₓ(OH)_{y}, wherein x may be 60, 70, 74, 76, or 78, and y may be 12 to 44).

According to another embodiment, a method of manufacturing a semiconductor device includes the chemical mechanical polishing method.

According to another embodiment, a chemical mechanical polishing device includes a platen configured to be rotatable, a hot liquid supply line configured to supply hot liquid to the inside of the platen, a polishing pad disposed on the platen, and a polishing slurry supplier disposed adjacent to the polishing pad to supply polishing slurry to the polishing pad.

The chemical mechanical polishing device may further include a hot liquid discharge line for discharging the hot liquid, the hot liquid discharge line being connected to the hot liquid supply line.

The chemical mechanical polishing device may further include a heating device for heating the liquid for supplying liquid to the inside of the platen to supply hot liquid.

The chemical mechanical polishing device may further include a temperature sensor for measuring a temperature of the hot liquid.

The chemical mechanical polishing device may further include a temperature sensor for measuring a surface temperature of the platen.

The chemical mechanical polishing device may further include a slurry heating device connected to the polishing slurry supplier.

The chemical mechanical polishing device may further include a temperature sensor for measuring a temperature of the polishing slurry.

A polishing rate may be improved while reducing structure damages and shape deformation of the semiconductor substrate.

### BRIEF DESCRIPTION OF THE DRAWINGS

FIG. 1 is a schematic view showing a chemical mechanical polishing device according to an embodiment, and

FIGS. 2 to 5 are each cross-sectional views showing a method of manufacturing a semiconductor device according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout. Example embodiments will hereinafter be described in detail, and may be easily performed by a person having an ordinary skill in the related art. However, this disclosure may be embodied in many different forms and is not to be construed as limited to the example embodiments set forth herein.

In the drawings, the thickness of layers, films, panels, regions, etc. are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, a chemical mechanical polishing device according to an embodiment is described.

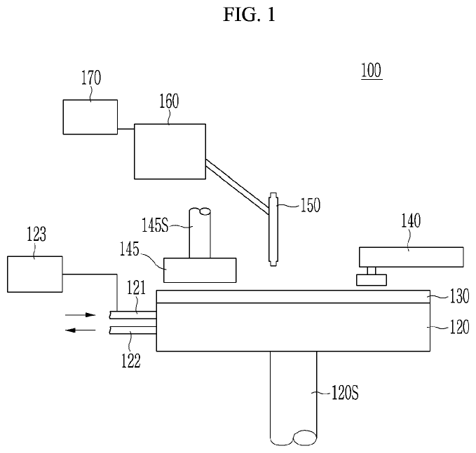

FIG. 1 is a schematic view showing a chemical mechanical polishing device according to an embodiment.

Referring to FIG. 1, a chemical mechanical polishing device 100 includes a platen 120; a polishing pad 130 disposed on the platen 120; a pad conditioner 140; a polishing head 145; and a polishing slurry supplier 150.

The platen 120 may be provided to be rotatable on the surface of the lower base (not shown). The platen 120 may receive rotation power from a motor (not shown) disposed inside the lower base and thus be rotated in a predetermined direction such as a clockwise direction or a counterclockwise direction by a rotating shaft 120S perpendicular to the surface of the platen 120.

The platen 120 may be equipped with at least one hot liquid supply line 121, through which hot liquid may be injected or passed to the inside of the platen. The hot liquid supply line 121 may be for example connected from an inlet of the platen 120 over the whole surface inside the platen 120. The inlet of the hot liquid supply line 121 may be for example formed at the side surface or the rear surface of the platen 120, and the hot liquid may be supplied along the hot liquid supply line 121 into the platen 120. The hot liquid passed along the hot liquid supply line 121 may be used to adjust, for example to raise, a surface temperature of the platen 120. The hot liquid supply line 121 may be formed of a heat resistance material not transformed at a high temperature.

The platen 120 may be additionally equipped with a hot liquid discharge line 122 for discharging the hot liquid. The hot liquid discharge line 122 may be connected to the hot liquid supply line 121 and used to discharge the hot liquid passing through the inside of the platen 120.

The polishing pad 130 may be disposed on the upper surface of the platen 120 and thus supported by the platen 120. The polishing pad 130 may be rotated with the platen 120. The polishing pad 130 may have a roughly-formed polishing surface, and the polishing surface may directly contact a polishing subject, that is, a semiconductor substrate such as a wafer and thus chemically and/or mechanically polish the surface of the semiconductor substrate. The polishing pad 130 may be formed of a porous material having a plurality of microspaces, i.e., microvoids, and the plurality of microspaces may accommodate polishing slurry.

The pad conditioner 140 may be adjacently disposed with the polishing pad 130 and maintain the surface roughness of the polishing surface of the polishing pad 130, so that the surface of the semiconductor substrate may be effectively polished during the polishing process. For example, the pad conditioner 140 may recover or maintain the surface roughness of the polishing pad 130 by polishing the surface of the polishing pad 130 during the polishing of the polishing subject or in a state of halting the polishing. The pad conditioner 140 may be rotated in a predetermined direction such as a clockwise direction or a counterclockwise direction along a predetermined rotating shaft.

The polishing head 145 may be disposed over the platen 120 and the polishing pad 130 and hold the polishing subject (not shown). The polishing subject may be for example the semiconductor substrate such as the wafer. The polishing head 145 may include a rotating shaft 145S rotating the polishing subject. When the polishing is performed, the polishing head 145 may be rotated in an opposite direction to that of the platen 130.

The polishing slurry supplier 150 is adjacently disposed to the polishing pad 130 and may be supplied with the polishing slurry from a polishing slurry tank 160. The polishing slurry supplier 150 discharges the polishing slurry on the polishing pad 130. The polishing slurry supplier 150 may include a nozzle capable of supplying the polishing slurry onto the polishing pad 130 during the polishing process. Moreover, a voltage supply unit (not shown) capable of applying a predetermined voltage to the nozzle may be used. The polishing slurry inside the nozzle may be electrically charged by the voltage applied from the voltage supply unit and discharged toward the polishing pad 130.

The chemical mechanical polishing device 100 may further include a heating device 123 to adjust the temperature of the hot liquid. The heating device 123 may be for example connected to the hot liquid supply line 121 and thus may heat a liquid for being supplied to the inside of the platen 120.

The chemical mechanical polishing device 100 may further include the slurry heating device 160 connected to the polishing slurry supplier 150. The slurry heating device 160 may be for example a heater. The slurry heating device 160 may preheat the slurry to be discharged through the polishing slurry supplier 150 and thus is used to adjust or raise the temperature of the polishing slurry, e.g., to a high temperature resulting in a greater removal rate.

The chemical mechanical polishing device 100 may be further equipped with at least one temperature sensor (not shown).

For example, the chemical mechanical polishing device 100 may be equipped with the temperature sensor connected to the hot liquid supply line 121 or the heating device 123. The temperature sensor connected to the hot liquid supply line 121 or the heating device 123 may be controlled to measure a temperature of the hot liquid supplied into the hot liquid supply line in real time and thus supply the hot liquid at a predetermined (e.g. constant) temperature.

For example, the chemical mechanical polishing device 100 may further include a temperature sensor (not shown) for measuring the surface temperature of the platen 120 and/or the polishing pad 130. The temperature sensor for measuring the surface temperature of the platen 120 and/or the polishing pad 130 may be controlled to measure the surface temperature of the platen 120 and/or the polishing pad 130 in real time before the polishing or during the polishing and thus perform the polishing at a predetermined temperature.

For example, the chemical mechanical polishing device 100 may further include a temperature sensor (not shown) connected to the hot liquid supply line polishing slurry supplier 150. The temperature sensor connected to the polishing slurry supplier 150 may be controlled to provide slurry at a predetermined (e.g. constant) temperature by measuring an appropriate temperature of slurry at room temperature or the polishing slurry heated in the slurry heating device 160.

The chemical mechanical polishing device 100 may further include a surface roughness measuring device (not shown) for measuring a surface roughness of the polishing pad 130. The surface roughness measuring device may precisely measure surface roughness of the polishing pad 130 in real time and thus realize predetermined (e.g. constant) polishing performance.

Hereinafter, a chemical mechanical polishing method according to an embodiment is described.

The chemical mechanical polishing method according to an embodiment may include preparing the aforementioned chemical mechanical polishing device 100, supplying a hot liquid to the inside of the platen 120 to increase the surface temperature of the platen 120, disposing the polishing subject such as the semiconductor substrate to face the polishing pad 130, supplying the polishing slurry between the polishing subject and the polishing pad 130, to polish the semiconductor substrate.

The hot liquid may be supplied through the aforementioned hot liquid supply line 121 to the inside of the platen 120 such as the entire internal surface of the platen 120. The hot liquid may include for example a liquid at about 35° C. to about 90° C., for example, water at about 35° C. to about 90° C.

As the hot liquid is supplied to the inside of the platen 120, the surface temperature of the platen 120 may be, for example, be adjusted or raised to a temperature in a range of about 30° C. to about 80° C., about 30° C. to about 70° C., about 30° C. to about 60° C., about 30° C. to about 50° C., or about 35° C. to about 45° C.

The surface temperature of the platen 120 may be substantially uniform across a surface of the platen, and accordingly, a center region and a peripheral region of the platen 120 may have a small or no surface temperature difference between the two regions. For example, a deviation of the surface temperature of the platen 120 depending on a location may be less than or equal to about 5 percent (%), less than or equal to about 3%, less than or equal to about 2%, or less than or equal to about 1%.

The supplying the hot liquid to the inside of the platen 120 may be performed before supplying the polishing slurry, and accordingly, if the polishing slurry is supplied on the polishing pad 130, the surface temperature of the platen 120 and the polishing pad 130 thereon may be increased. However, the present invention is not limited thereto, and the hot liquid may be continuously or discontinuously supplied during the supplying the polishing slurry and/or the polishing as well as before supplying the polishing slurry.

In this way, polishing efficiency and a polishing rate may be improved by supplying the polishing slurry on the polishing pad 130 of which the surface temperature is increased. The increase in temperature is believed to increase a chemical reaction rate between the polishing slurry and the polishing subject. Particularly, as described later, carbon abrasives having several nanometers size exhibit excellent polishing. It is believed that the observed improvement may result in part from a chemical interaction rather than, or in addition, to mechanical polishing. This chemical interaction can be a chemical reaction or a chelating effect, and thus, minimize structural damage to the polished substrate.

The polishing slurry may include the abrasive.

The abrasive may include the carbon abrasives, and the carbon abrasives may consist of carbon or be abrasives including carbon, for example, two dimensional or three dimensional particles consisting of the carbon or including the carbon as a main component.

The carbon abrasives may, for example, have an average particle diameter of less than about 10 nanometers (nm). The carbon abrasives have a small average particle diameter within the range and accordingly, may be applied to fine pitch structures having a width of less than about 10 nm and thus reduce or prevent a structural damage such as a scratch or dishing. Within the range, the average particle diameter of the carbon abrasives may be less than or equal to about 8 nm, less than or equal to about 7 nm, less than or equal to about 5 nm, for example less than or equal to about 3 nm, for example less than or equal to about 2 nm, for example less than or equal to about 1 nm. For example, the average particle diameter of the carbon abrasives may be greater than or equal to about 0.01 nm and less than 10 nm, about 0.01 nm to about 8 nm, about 0.01 nm to about 7 nm, about 0.01 nm to about 5 nm, about 0.01 nm to about 3 nm, about 0.01 nm to about 2 nm, or about 0.01 nm to about 1 nm.

These carbon abrasives exhibit improved or excellent chemical polishing compared to mechanical polishing, unlike large oxide abrasives having tens of nanometer diameters such as silica or alumina. The chemical reaction between the polishing slurry and the polishing subject may be important, as described above. Accordingly, as described above, the polishing slurry may be supplied on the platen 130 having an increased surface temperature to promote this chemical reaction and thus increase the polishing rate.

For example, the carbon abrasives may include fullerene or a derivative thereof, graphene, graphite, a carbon nanotube, a carbon dot, or a combination thereof.

For example, the carbon abrasives may include fullerene or fullerene derivative. The fullerene may be, for example a C60, C70, C74, C76, or C78 fullerene, but is not limited thereto. The fullerene or fullerene derivative may be used in combination with graphene, graphite, a carbon nanotube, a carbon dot, or a combination thereof.

For example, the fullerene derivative may be hydrophilic fullerene and the hydrophilic fullerene may have a structure in which at least one hydrophilic functional group is bound to a fullerene core. The fullerene core may be for example a C60, C70, C74, C76, or C78 core, but is not limited thereto. The hydrophilic functional group may be for example at least one selected from a hydroxyl group, an amino group, a carbonyl group, a carboxylic group, a sulfhydryl group, or a phosphate group, but is not limited thereto. The hydrophilic functional group may be for example a hydroxyl group. In an embodiment, the fullerene derivative is the hydrophilic fullerene as described above.

The hydrophilic fullerene may include at least 2 hydrophilic functional groups in average, for example 2 to 44 hydrophilic functional groups in average, 8 to 44 hydrophilic functional groups in average, 12 to 44 hydrophilic functional groups in average, 24 to 44 hydrophilic functional groups in average, 24 to 40 hydrophilic functional groups in average, 24 to 38 hydrophilic functional groups in average, 32 to 44 hydrophilic functional groups in average, 32 to 40 hydrophilic functional groups in average, or 32 to 38 hydrophilic functional groups in average per the fullerene core.

For example, the hydrophilic fullerene may be hydroxyl fullerene, and may be for example represented by Cₓ(OH)_{y} (wherein, x may be 60, 70, 74, 76, or 78 and y may be 2 to 44). Herein, the average hydroxyl group number y of the hydroxyl fullerene may be determined by a method such as elemental analysis, thermogravimetric analysis, spectroscopic analysis, mass spectrometry, and the like, and may be for example an average value of the highest two peaks in a liquid chromatography mass spectrum (LCMS).

For example, the hydrophilic fullerene may be hydroxyl fullerene, and may be for example represented by Cₓ(OH)_{y} (wherein, x may be 60, 70, 74, 76, or 78 and y may be 12 to 44).

For example, the hydrophilic fullerene may be hydroxyl fullerene, and may be for example represented by Cₓ(OH)_{y} (wherein, x may be 60, 70, 74, 76, or 78 and y may be 24 to 44).

For example, the hydrophilic fullerene may be hydroxyl fullerene, and may be for example represented by Cₓ(OH)_{y} (wherein, x may be 60, 70, 74, 76, or 78 and y may be 32 to 44).

The hydroxyl fullerene may be effectively dispersed in water.

The carbon abrasives may be included in an amount of about 0.01 weight percent (wt %) to about 5 wt % based on a total weight of the polishing slurry. Within the range, the carbon abrasives may be included in an amount of about 0.01 wt % to about 3 wt %, about 0.01 wt % to about 2 wt %, about 0.01 wt % to about 1 wt %, about 0.01 wt % to about 0.8 wt %, or about 0.01 wt % to about 0.5 wt %, based on a total weight of the polishing slurry.

The abrasive may further include other abrasives in addition to the carbon abrasives.

The polishing slurry may further include an additive and the additive may be for example a chelating agent, an oxidizing agent, a surfactant, a dispersing agent, a pH controlling agent, or a combination thereof, but is not limited thereto.

The chelating agent may be for example phosphoric acid, nitric acid, citric acid, malonic acid, a salt thereof, or a combination thereof, but is not limited thereto.

The oxidizing agent may be, for example, hydrogen peroxide, hydrogen peroxide water, sodium hydroxide, potassium hydroxide, or a combination thereof, but is not limited thereto.

The surfactant may be an ionic or non-ionic surfactant, for example, a copolymer of ethylene oxide, a copolymer of propylene oxide, an amine compound, or a combination thereof, but is not limited thereto.

The dispersing agent may promote the dispersion of the carbon abrasives, and for example, include a water-soluble monomer, a water-soluble oligomer, a water-soluble polymer, a metal salt, or a combination thereof. A weight average molecular weight of the water-soluble polymer may be for example less than or equal to about 10,000 grams per mole (g/mole), for example, less than or equal to about 5000 g/mole, or for example, less than or equal to about 3000 g/mole. The metal salt may be, for example, copper salt, nickel salt, cobalt salt, manganese salt, tantalum salt, ruthenium salt, or a combination thereof. The dispersing agent may be, for example, a poly(meth)acrylic acid, poly(meth)acryl maleic acid, polyacrylonitrile-co-butadiene-acrylic acid, carboxylic acid, sulfonic ester, sulfonic acid, phosphoric ester, cellulose, diol, a salt thereof, or a combination thereof, but is not limited thereto.

The pH controlling agent may control pH of the polishing slurry, and may be for example, an inorganic acid, organic acid, a salt thereof, or a combination thereof. The inorganic acid may include, for example, nitric acid, hydrochloric acid, phosphoric acid, sulfuric acid, hydrofluoric acid, bromic acid, iodic acid or a salt thereof, the organic acid may include, for example, formic acid, malonic acid, maleic acid, oxalic acid, adipic acid, citric acid, acetic acid, propionic acid, fumaric acid, lactic acid, salicylic acid, benzoic acid, succinic acid, phthalic acid, butyric acid, glutaric acid, glutamic acid, glycolic acid, lactic acid, aspartic acid, tartaric acid, or a salt thereof, but they are not limited thereto.

Each additive independently may be included in a trace amount of about 1 part per million by weight (ppm) to about 100,000 ppm, but is not limited thereto.

The polishing slurry may further include a solvent capable of dissolving or dispersing the above components, and the solvent may be for example water. The water may be for example distilled water and/or deionized water.

In an embodiment, the polishing slurry is heated to a temperature higher than room temperature and then, supplied to the polishing pad 130. In order to supply this heated polishing slurry, the heating of the polishing slurry may be further included before supplying the polishing slurry on the polishing pad 130. The heating of the polishing slurry may be performed at a lower temperature than a boiling point of the polishing slurry, but a higher temperature than the room temperature, for example, at a temperature of about 27° C. to about 90° C., about 27° C. to about 80° C., about 27° C. to about 70° C., about 27° C. to about 60° C., about 30° C. to about 90° C., about 30° C. to about 80° C., about 30° C. to about 70° C., or about 30° C. to about 60° C. The heated polishing slurry supplied to a polishing subject may increase a chemical interaction, for example, an increase in chemical reaction rate between the polishing slurry and the polishing subject, and accordingly, the polishing efficiency and the polishing rate may be further improved.

For example, the polishing slurry may be supplied for example at about 10 milliliters per minute (ml/min) to about 100 ml/min, for example, about 20 ml/min to 70 ml/min (a flow rate).

The polishing may be performed by contacting the surface of the polishing subject and the polishing pad and rotating them. A rotating direction of the polishing subject may be opposite to that of the platen 120 but is not limited thereto. The polishing may be performed by applying a predetermined pressure of for example, about 1 pounds per square inch (psi) to about 5 psi, about 1.2 psi to about 3 psi, about 1.3 psi to about 3 psi, about 2 psi to about 2 psi, or about 1.3 psi to about 2.3 psi.

The polishing method described above may result in little or no heat by a mechanical friction using the carbon abrasives having a several nanometers size, which is not the case for the larger oxide abrasives having tens of nanometer diameter such as silica or alumina. Accordingly, the polishing method may not require a separate cooling step unlike the polishing with the large oxide abrasives having tens of nanometer diameter such as silica or alumina as an abrasive, which generally does require separate cooling.

The above chemical mechanical polishing method may be applied during formation of various structures, for example, effectively applied to the polishing of a conductor such as a metal line. For example, the aforementioned chemical mechanical polishing method may be used to polish the conductor such as the metal line in the semiconductor substrate, for example, a conductor such as copper (Cu), tungsten (W), or an alloy thereof.

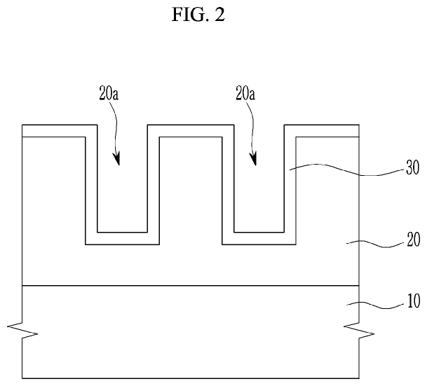

FIGS. 2 to 5 are cross-sectional views showing a method of manufacturing a semiconductor device according to an embodiment.

Referring to FIG. 2, an interlayer insulating layer 20 is formed on a semiconductor substrate 10. The interlayer insulating layer 20 may include an oxide, a nitride, and/or an oxynitride. Subsequently, the interlayer insulating layer 20 is etched to form a trench 20a. The trench 20a may have a width of less than or equal to about 20 nm, less than or equal to about 15 nm, or less than or equal to about 10 nm. Subsequently, a barrier layer 30 is formed on the wall surface of the trench. The barrier layer 30 may for example include Ta and/or TaN but is not limited thereto.

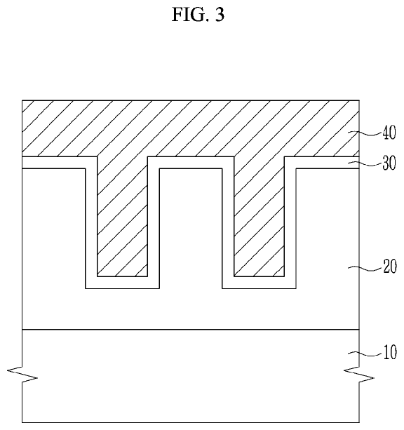

Referring to FIG. 3, a metal such as copper (Cu) is filled inside the trench and thus forms a metal layer 40.

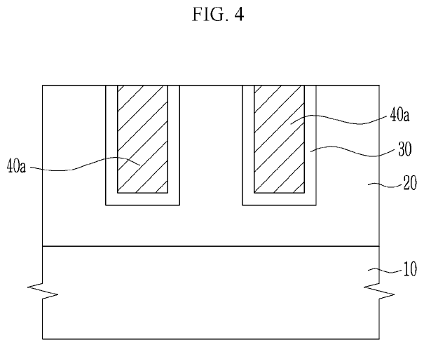

Referring to FIG. 4, the surface of the metal layer 40 is planarized to coincide with the surface of the interlayer insulating layer 20 to form a filled metal layer 40a. The planarization may be performed through chemical mechanical polishing as described, that is, by using the aforementioned chemical mechanical polishing device. Specific details are the same as above. For example, when the barrier layer 30 is a Ta layer, the metal layer 40 is a Cu layer, and the higher polishing selectivity of Ta relative to Cu of the polishing slurry may be selectively adjusted, for example, the polishing selectivity of Ta may be higher than that of Cu, for example, about 50:1, or higher.

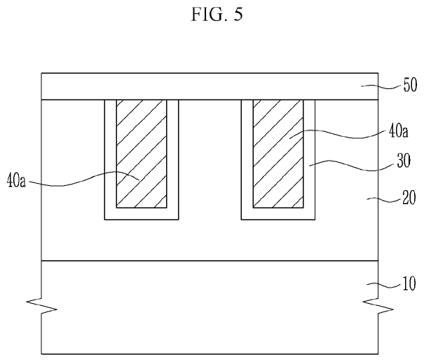

Referring to FIG. 5, a capping layer 50 is formed on the filled metal layer 40a and the interlayer insulating layer 20. The capping layer 50 may include SiN and/or SiC but is not limited thereto.

As described above, the method of manufacturing a semiconductor device according to an embodiment has been described, but it is not limited thereto, and it may be employed for a semiconductor device having the various structures.

Hereinafter, the embodiments are illustrated in more detail with reference to examples. However, these examples are exemplary, and the present disclosure is not limited thereto.

### Preparation Example: Preparation of Polishing Slurry

### (1) Synthesis of Hydroxyl Fullerene

A vessel for a beads mill having a height of about 100 millimeters (mm) and a diameter of about 50 mm is filled with beads up to ⅓ volume of the vessel, and then, 1 grams (g) of fullerene (C60, Nanom purple ST, Frontier Carbon Corp.), 0.5 grams per Liter (g/L) of a dispersing agent (polyacrylic acid, Mw 1800, Merck & Co., Inc.), and 100 g of water are added to the vessel. The beads include 50 g of zirconia beads having an average particle diameter of 500 micrometers (μm), 50 g of zirconia beads having an average particle diameter 5 mm, and 50 g of zirconia beads having an average particle diameter of 10 mm.

After spinning the vessel for 40 hours, a sample is taken out to measure an average particle diameter of the fullerene. The particle diameter is measured by using a dynamic light scattering-type particle diameter distribution analyzer (Zeta-potential & Particle Size Analyzer ELS-Z, Otsuka Electronics Co., Ltd.).

After confirming that the sample of fullerene has an average particle diameter of less than or equal to 100 nanometers (nm), 100 g of a 30 weight percent (wt %) hydrogen peroxide solution is added to the vessel, and the beads are removed from the vessel. The sample mixture is stirred at about 70° C. for 8 days to prepare a dispersion of hydroxyl fullerene.

An average particle diameter of hydroxyl fullerene is measured by using a dynamic light scattering-type particle diameter distribution analyzer (Zeta-Potential & Particle Size Analyzer ELS-Z).

The average number of hydroxy groups of the hydroxyl fullerene is evaluated by Fourier transform infrared spectroscopy (FTIR) method by averaging the two highest peaks of a spectrum of the hydroxyl fullerene. The resulting hydroxyl fullerene is represented by C₆₀(OH)₃₄ with an average particle diameter of 2.5 nm and an average hydroxy group number of 34.

### (2) Preparation of Polishing Slurry

0.1 wt % of hydroxyl fullerene represented by C₆₀(OH)₃₄, 0.03 wt % of benzotriazole, 1.5 wt % of tris-ammonium citrate, and 0.4 wt % of phosphoric ammonium dihydrogen phosphate are mixed with water to prepare a polishing slurry.

### EXAMPLES

### Example 1

Hot water at 80° C. is passed through a hot liquid supply line of a polishing device shown in FIG. 1 and maintained for 30 minutes, and then, polishing is performed under the following conditions.

(1) Polishing subject (wafer): a 12-inch silicon wafer with a Cu film having a thickness of 1.5 μm

(2) Polishing pad: IC1000 (Dow Chemical Company)

(3) The number of polishing head rotation: 87 revolutions per minute (rpm)

(4) Diameter/thickness of polishing platen: 765 mm/65 mm

(5) The number of polishing platen rotation: 93 rpm

(6) Applied pressure: 2 to 3 pounds per square inch (psi)

(7) Polishing slurry: polishing slurry including C₆₀(OH)₃₄ according to Preparation Example

(8) Temperature of polishing slurry: room temperature (24° C.)

(9) Method of supplying polishing slurry: after discharging 100 milliliters (ml) of polishing slurry on a polishing pad, polishing is performed.

(10) Polishing time: 60 seconds

### Example 2

Polishing is performed according to the same method as Example 1 except that the polishing slurry at 80° C. obtained by heating a polishing slurry tank with an external heater is used.

### Comparative Example 1

Polishing is performed according to the same method as Example 1 except that the passage of hot water at 80° C. before the polishing is omitted. A surface temperature of the platen is room temperature (about 24° C.).

### Evaluation I

A surface temperature change of the platen is measured and depends on the amount of time after the passage of hot water at 80° C. through the hot liquid supply line into the polishing device.

The results are the same as shown in Table 1.

TABLE 1

| Time (min) | Surface temperature of platen (° C.) |
|---|---|
| 0 | 25 |
| 10 min | 40 |
| 20 min | 55 |
| 30 min | 64 |

Referring to Table 1, the surface temperature of the platen after supplying water at about 80° C. through the hot liquid supply line of the polishing device is shown to slowly increase, and reaches about 64° C. after about 30 minutes. In Examples 1 and 2, the surface temperature of the platen is about 64° C., when the polishing is performed.

### Evaluation II

After performing the polishing for 60 seconds for each of Example 1, Example 2, and Comparative Example 1, a polishing rate (a material removal rate, MRR) is evaluated. The surface temperature of the platen is measured by using an IR thermometer equipped in a polishing device. The polishing rate is calculated by obtaining a thickness of a metal (Cu) film using an electrical resistance and converting the resistance into a removal rate.

The results are shown in Table 2.

TABLE 2

| | Surface temperature | Slurry temperature | MRR |
|---|---|---|---|
| | of platen (° C.) | (° C.) | (nm/min) |
| Example 1 | 64 | 24 | 625 |
| Example 2 | 64 | 80 | 1000 |
| Comparative | RT (about 24° C.) | RT (about 24° C.) | 105 |
| Example 1 | | | |

RT: Room Temperature

Referring to Table 1, if the polishing is performed according to Examples 1 and 2, the polishing rate can be increased significantly compared to the polishing performed according to the Comparative Example.

While this disclosure has been described in connection with what is presently considered to be practical example embodiments, it is to be understood that the invention is not limited to the disclosed embodiments. On the contrary, it is intended to cover various modifications and equivalent arrangements included within the spirit and scope of the appended claims.

What is claimed is:

1. A chemical mechanical polishing method comprising
preparing a chemical mechanical polishing device comprising a platen, a polishing pad, and a polishing slurry supplier,
supplying a hot liquid to an inside of the platen to adjust a surface temperature of the platen,
disposing the semiconductor substrate and the polishing pad to face each other,
supplying polishing slurry comprising carbon abrasives having an average particle diameter of less than about 10 nanometers between the semiconductor substrate and the polishing pad, and
contacting the surface of the semiconductor substrate with the polishing pad to polish the semiconductor substrate.

2. The chemical mechanical polishing method of claim 1, wherein a temperature of the hot liquid is about 35° C. to about 90° C.

3. The chemical mechanical polishing method of claim 1, wherein a surface temperature of the platen is about 30° C. to about 80° C.

4. The chemical mechanical polishing method of claim 3, wherein the surface temperature of the platen is about 35° C. to about 45° C.

5. The chemical mechanical polishing method of claim 1, wherein
the chemical mechanical polishing device comprises a hot liquid supply line connected to the platen, and the hot liquid is supplied inside the platen through the hot liquid supply line.

6. The chemical mechanical polishing method of claim 1, wherein the adjusting of the surface temperature of the platen is performed before the supplying of the polishing slurry.

7. The chemical mechanical polishing method of claim 1, wherein after the adjusting of the surface temperature of the platen, a deviation of the surface temperature according to a position of the platen is less than or equal to about 5%.

8. The chemical mechanical polishing method of claim 1, further comprising heating the polishing slurry before the supplying of the polishing slurry.

9. The chemical mechanical polishing method of claim 8, wherein the heating of the polishing slurry comprises heating the polishing slurry to a temperature of about 27° C. to about 90° C.

10. The chemical mechanical polishing method of claim 1, wherein the hot liquid comprises hot water.

11. The chemical mechanical polishing method of claim 1, wherein the carbon abrasives comprise fullerene or a fullerene derivative.

12. The chemical mechanical polishing method of claim 11, wherein
the carbon abrasives comprise a hydrophilic fullerene having at least one hydrophilic functional group, and the hydrophilic functional group comprises at least one of a hydroxyl group, an amino group, a carbonyl group, a carboxylic group, a sulfhydryl group, or a phosphate group.

13. The chemical mechanical polishing method of claim 11, wherein the carbon abrasives comprise hydroxyl fullerene represented by Cₓ(OH)_{y}, wherein, x is 60, 70, 74, 76, or 78 and y is 12 to 44.

14. A method of manufacturing a semiconductor device comprising the chemical mechanical polishing method of claim 1.

15. A chemical mechanical polishing device comprising
a platen configured to be rotatable,
a hot liquid supply line configured to supply hot liquid inside the platen,
a polishing pad disposed on the platen, and
a polishing slurry supplier disposed adjacent to the polishing pad to supply polishing slurry to the polishing pad.

16. The chemical mechanical polishing device of claim 15, further comprising a hot liquid discharge line for discharging the hot liquid, the hot liquid discharge line being connected to the hot liquid supply line.

17. The chemical mechanical polishing device of claim 15, further comprising a heating device for heating a liquid for the supplying hot liquid inside the platen.

18. The chemical mechanical polishing device of claim 15, further comprising a temperature sensor for measuring a temperature of the hot liquid.

19. The chemical mechanical polishing device of claim 15, further comprising a temperature sensor for measuring a surface temperature of the platen.

20. The chemical mechanical polishing device of claim 15, further comprising a slurry heating device for heating the polishing slurry.

21. The chemical mechanical polishing device of claim 20, further comprising a temperature sensor for measuring a temperature of the polishing slurry.
